(19) United States
(12) Patent Application Publication
(10) Pub. No.: US 2026/0173437 A1
(43) Pub. Date: Jun. 18, 2026

(54) SEMICONDUCTOR STRUCTURE AND FABRICATION METHOD THEREOF

(71) Applicant: Semiconductor Manufacturing International (Shanghai) Corporation, Shanghai (CN)

(72) Inventors: Jisong JIN, Shanghai (CN); Yang DONG, Shanghai (CN); Sha JIN, Shanghai (CN)

(21) Appl. No.: 19/423,461

(22) Filed: Dec. 17, 2025

(30) Foreign Application Priority Data
Dec. 17, 2024 (CN) 202411872128.7
Jul. 18, 2025 (CN) 202511002042.3

(51) Int. Cl. H10D 30/00; H10D 30/01

(52) U.S. Cl. CPC H10D 30/503; H10D 30/0193; H10D 30/0196; H10D 30/508

(57) ABSTRACT

A semiconductor structure and a fabrication method of the semiconductor structure are provided in the present disclosure. The semiconductor structure includes a base substrate; one or more channels over the base substrate; a gate structure around the one or more channels along a vertical direction, where the gate structure includes at least one first gate-structure portion each around a channel of the one or more channels; and first spacers on two sides of each first gate-structure portion along a lateral direction. A portion of the channel extends into between the first gate-structure portion and a corresponding first spacer.

### CROSS-REFERENCE TO RELATED APPLICATION

This application claims the priority of Chinese Patent Application No. 202411872128.7, filed on Dec. 17, 2024, and No. 202511002042.3, filed on Jul. 18, 2025, the content of all which is incorporated herein by reference in their entirety.

### TECHNICAL FIELD

The present disclosure generally relates to the field of semiconductor manufacturing and, more particularly, relates to a semiconductor structure and a fabrication method thereof.

### BACKGROUND

In semiconductor manufacturing, with the development trend of super large-scale integrated circuits, the feature sizes of integrated circuits continue to decrease. To adapt to smaller feature sizes, the channel lengths of metal-oxide-semiconductor field-effect transistors (MOSFET) have also been reduced accordingly. However, as the device channel length is reduced, the distance between a source electrode and a drain electrode of the device may also be reduced. Therefore, the gate structure's ability to control the channel may become worse, and it may be increasingly difficult for the gate voltage to pinch off the channel, which may result in subthreshold leakage phenomenon. That is, so-called short-channel effects (SCE) may be more likely to occur.

Therefore, to better adapt to the requirements of scaling down device sizes, semiconductor processes have gradually begun to transition from planar transistors to three-dimensional transistors with higher efficiency, such as gate-all-around (GAA) transistors. In the gate-all-around metal gate transistor, a gate structure may surround the region where the channel is located from all sides. Compared with the planar transistor, the gate structure of the gate-all-around metal gate transistor may have stronger control over the channel and better suppress the short channel effect.

### SUMMARY

One aspect of the present disclosure provides a semiconductor structure. The semiconductor structure includes a base substrate; one or more channels over the base substrate; a gate structure around the one or more channels along a vertical direction, where the gate structure includes at least one first gate-structure portion each around a channel of the one or more channels; and first spacers on two sides of each first gate-structure portion along a lateral direction, where a portion of the channel extends into between the first gate-structure portion and a corresponding first spacer.

Optionally, along the vertical direction, the first gate-structure portion and the corresponding first spacer are partially connected for providing an upper opening and a bottom opening there-between, and the portion of the channel extends into both the upper opening and the bottom opening.

Optionally, the channel includes a channel layer and a compensation layer on two sides of the channel layer; and the compensation layer extends into between the first gate-structure portion and the corresponding first spacer.

Optionally, along the vertical direction, the first gate-structure portion and the corresponding first spacer are partially connected for providing an upper opening and a bottom opening there-between, and the compensation layer extends into both the upper opening and the bottom opening.

Optionally, along an extension direction of the channel layer, a thickness of the compensation layer is about 20 Å to 150 Å.

Optionally, the channel layer is made of a material including silicon, germanium, silicon germanium, a Group III-V semiconductor material, or a combination thereof.

Optionally, a material of the compensation layer is same as the material of the channel layer.

Optionally, the compensation layer is made of a material including silicon.

Optionally, the first spacer protrudes over a sidewall of the channel layer along the lateral direction; and along an extension direction of the channel layer, a thickness of the first spacer is about 10 Å to 100 Å.

Optionally, the first spacer is made of silicon nitride, silicon oxide, silicon oxycarbide, and silicon oxycarbonitride, and/or a combination thereof.

Optionally, the semiconductor structure further includes a source-drain doped layer, on the base substrate at two sides of the gate structure and in contact with the one or more channels.

Another aspect of the present disclosure provides a fabrication method of a semiconductor structure. The method includes providing a base substrate, where a stacked-layer structure is formed on the base substrate and includes sacrificial layers and channel layers alternately stacked along a vertical direction; removing a portion of a sacrificial layer along a lateral direction from a sidewall of the stacked-layer structure to form a first groove surrounded by adjacent channel layers along the vertical direction; forming a first spacer in the first groove; removing a portion of a channel layer along the lateral direction and a portion of a sacrificial layer from a sidewall of the stacked-layer structure to form a second groove surrounded by adjacent first spacers along the vertical direction, where the second groove extends into the sacrificial layer and exposes a portion of the sacrificial layer in contact with the first spacer; forming a compensation layer for filling the second groove; removing the sacrificial layers and retaining one or more channel layers spaced apart from each other and suspended over the base substrate; and forming a gate structure crossing the stacked-layer structure, where the gate structure surrounds the one or more channel layers.

Optionally, forming the first spacer in the first groove includes forming a spacer material layer covering a sidewall of the channel layer and filling the first groove; and removing the spacer material layer on the sidewall of the channel layer and retaining the spacer material layer in the first groove as the first spacer.

Optionally, removing the portion of the channel layer along the lateral direction and the portion of the sacrificial layer from the sidewall of the stacked-layer structure to form the second groove surrounded by adjacent first spacers along the vertical direction includes removing the portion of the channel layer along the lateral direction from the sidewall of the stacked-layer structure to form the second groove exposing the portion of the sacrificial layer in contact with the first spacer; and removing a portion of the sacrificial layer exposed at a top and a bottom of the first spacer, such that the second groove extend into the sacrificial layer.

Optionally, an isotropic etching process is configured to remove the portion of the channel layer along the lateral direction from the sidewall of the stacked-layer structure to form the second groove exposing the portion of the sacrificial layer in contact with the first spacer; and/or in the isotropic etching process, an etching selectivity ratio between the channel layer and the sacrificial layer is greater than or equal to 3, and an etching selectivity ratio between the channel layer and the first spacer is greater than or equal to 3.

Optionally, an isotropic etching process is configured to remove the portion of the sacrificial layer exposed at the top and the bottom of the first spacer, such that the second groove extend into the sacrificial layer; and/or in the isotropic etching process, an etching selectivity between the sacrificial layer and the channel layer is greater than or equal to 5, and an etching selectivity between the sacrificial layer and the first spacer is greater than or equal to 5.

Optionally, an isotropic etching process is configured to remove the portion of the channel layer along the lateral direction and the portion of the sacrificial layer from the sidewall of the stacked-layer structure to form the second groove surrounded by adjacent first spacers along the vertical direction; and the second groove extends into the sacrificial layer and exposes the portion of the sacrificial layer in contact with the first spacer; and/or in the isotropic etching process, an etching selectivity ratio between the channel layer and the sacrificial layer is greater than or equal to 3.

Optionally, for removing the portion of the channel layer along the lateral direction and the portion of the sacrificial layer from the sidewall of the stacked-layer structure to form the second groove surrounded by adjacent first spacers along the vertical direction, a width of the second groove is about 20 Å to 150 Å.

Optionally, an epitaxial growth process is configured to form the compensation layer for filling the second groove; and/or for forming the compensation layer for filling the second groove, a material of the compensation layer is same as a material of the channel layer; and/or for providing the base substrate, the channel layer is made of a material including silicon, germanium, silicon germanium, a Group III-V semiconductor material, or a combination thereof; and the sacrificial layer is made of a material including silicon germanium.

Optionally, before removing the sacrificial layer, the method further includes forming a source-drain doped layer on the base substrate at two sides of the stacked-layer structure, where the source-drain doped layer is in contact with the compensation layer and the first spacer.

Compared with the existing technology, the technical solutions provided by the present disclosure may achieve at least the following beneficial effects.

In the semiconductor structure provided by embodiments of the present disclosure, the portion of the channel may extend into between the first gate-structure portion and corresponding first spacer, which may increase the thickness of the isolation between the first gate-structure portion and an external structure by the first spacer, thereby enhancing the isolation between the first gate-structure portion and external structure by the first spacer and improving the performance of the semiconductor structure.

The fabrication method provided by embodiments of the present disclosure includes removing the portion of the channel layer along the lateral direction and the portion of the sacrificial layer from the sidewall of the stacked-layer structure to form the second groove surrounded by adjacent first spacers along the vertical direction, where the second groove extends into the sacrificial layer and exposes a portion of the sacrificial layer in contact with the first spacer; forming the compensation layer for filling the second groove; removing the sacrificial layers and retaining one or more channel layers spaced apart from each other and suspended over the base substrate; and forming the gate structure crossing the stacked-layer structure. The gate structure surrounds the one or more channel layers; and the gate structure between adjacent channel layers and between the channel layer structure and the base substrate are in contact with the first spacer. In embodiments of the present disclosure, the gate structure and the external structure (i.e., the source-drain doped layer) may be isolated (separated) from each other by the first spacers and the compensation layer; and the second groove may extend from between vertically adjacent first spacers into the sacrificial layer. That is, the second groove may extend to the positions where the top and bottom of the first spacers are in contact with the sacrificial layer. Therefore, the compensation layer may increase the thickness of the isolation between the gate structure and the external structure at the top and bottom of the first spacer, thereby being beneficial for enhancing the isolation between the gate structure and the external structure. Furthermore, during subsequent removal of the sacrificial layer, the compensation layer and the first spacer may together protect the sidewalls of the external structure, thereby being beneficial for reducing the probability of damage to the external structure and further improving the performance of the semiconductor structure.

### BRIEF DESCRIPTION OF THE DRAWINGS

The following drawings are merely examples for illustrative purposes according to various disclosed embodiments and are not intended to limit the scope of the present disclosure.

FIG. 1 illustrates a structural schematic of an exemplary semiconductor structure.

FIG. 2 illustrates a structural schematic of an exemplary semiconductor structure according to various disclosed embodiments of the present disclosure.

FIG. 3 illustrates another structural schematic of an exemplary semiconductor structure according to various disclosed embodiments of the present disclosure.

FIGS. 4-12 illustrate structural schematics corresponding to certain stages of a fabrication method of an exemplary semiconductor structure.

FIG. 13 illustrates a flowchart of a fabrication method of an exemplary semiconductor structure according to various disclosed embodiments of the present disclosure.

### DETAILED DESCRIPTION

References are made in detail to exemplary embodiments of the disclosure, which are illustrated in accompanying drawings. Wherever possible, same reference numbers are used throughout accompanying drawings to refer to same or like parts.

A semiconductor structure and a fabrication method of the semiconductor structure are provided in the present disclosure. The semiconductor structure includes a base substrate; one or more channels over the base substrate; a gate structure around the one or more channels along a vertical direction, where the gate structure includes at least one first gate-structure portion each around a channel of the one or more channels; and first spacers on two sides of each first gate-structure portion along a lateral direction, where a portion of the channel extends into between the first gate-structure portion and a corresponding first spacer.

Currently, in the process of the gate-all-around transistor, an inner spacer process may be needed to form separation (spacing) between a source-drain doped layer and a gate structure, thereby controlling and reducing the leakage and capacitance between the gate structure and the source-drain doped layer.

Furthermore, during nanosheet release in the gate-all-around transistor process, the inner spacer may be also configured as a blocking structure for the selective removal of a sacrificial channel layer, thereby preventing such process damaging the source-drain doped layer.

However, in actual process, the inner spacer may be relatively thin near the channel layer during the formation of the inner spacer, which may result in that the inner spacer is not capable to prevent damage to the source-drain doped layer during the selective removal of the sacrificial channel layer. Therefore, the inner spacer process may need to be improved. The present disclosure aims to address such weaknesses in the inner spacer. After the inner spacer is formed, a portion of a channel layer and a sacrificial channel layer may be etched back, and a compensation layer may be formed. The compensation layer and the inner spacer may together form the blocking structure for the nanosheet release process, thereby desirably protecting the source-drain doped layer.

The present disclosure provides a fabrication method of a semiconductor structure to overcome above-mentioned problems.

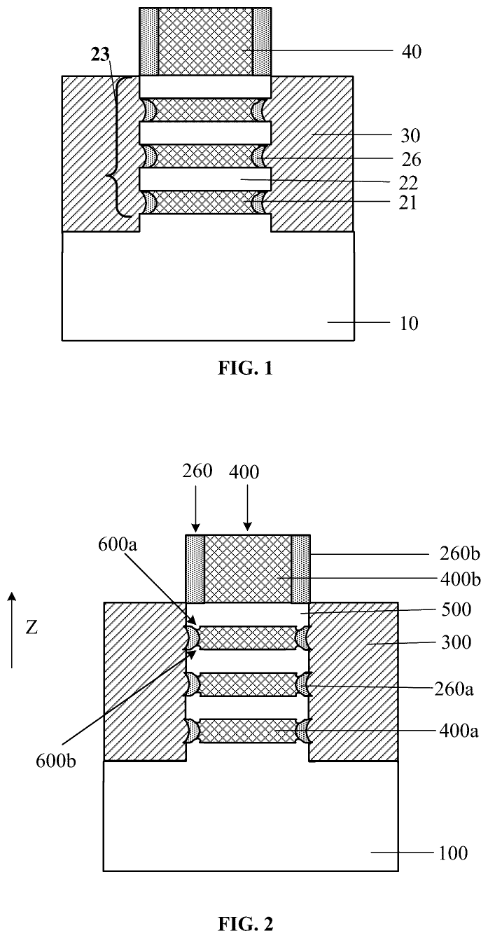

FIG. 1 illustrates a structural schematic of an exemplary semiconductor structure.

Referring to FIG. 1, the semiconductor structure may include a substrate 10; a channel layer structure 23 suspended above the base substrate 10, where the channel layer structure 23 may include one or more channel layers 22 spaced along the vertical direction; a gate structure 40 on the base substrate 10 and crossing the channel layer structure 23, where the gate structure 40 may be around the channel layers 22 along the extension direction of the gate structure 40, and the gate structure 40 between adjacent channel layers 22 and between the channel layer structure 23 and the base substrate 10 may be configured as a stacked-layer gate 21; spacers 26 on the sidewalls of the stacked-layer gate 21; and a source-drain doped layers 30, on the base substrate 10 at two sides of the gate structure 40 and in contact with the spacers 26.

During the semiconductor process, when the spacer 26 is formed, the filling of the middle portion of the spacer 26 is easier than the filling of the upper and lower sides (edges) of the spacer 26 which is in contact with the channel layer 22, such that it may be easy to form a sickle-shaped morphology that gradually becomes thinner from the middle to the edge. When the gate structure 40 is formed, the edge of the spacer 26 may provide weak protection for the source-drain doped layer 30, which may easily damage the source-drain doped layer 30 through the edge of the spacer 26. Therefore, it may easily result in that the edge of the spacer 26 provides poor isolation between the stacked-layer gate 21 and the source-drain doped layer 30, which may affect the performance of the semiconductor structure.

To solve above-mentioned technical problems, embodiments of the present disclosure provide a semiconductor structure. The semiconductor structure may include a substrate; one or more channels over the base substrate; a gate structure around the one or more channels along a vertical direction, where the gate structure includes at least one first gate-structure portion each around a channel of the one or more channels; and first spacers on two sides of each first gate-structure portion along a lateral direction, where a portion of the channel extends into between the first gate-structure portion and a corresponding first spacer.

In embodiments of the present disclosure, the portion of the channel may extend into between the first gate-structure portion and corresponding first spacer, which may increase the thickness of the isolation between the first gate-structure portion and an external structure by the first spacer, thereby enhancing the isolation between the first gate-structure portion and external structure by the first spacer and improving the performance of the semiconductor structure.

In order to clearly illustrate above-mentioned described objectives, features, and advantages of the present disclosure, various embodiments of the present disclosure are described in detail with reference to accompanying drawings hereinafter.

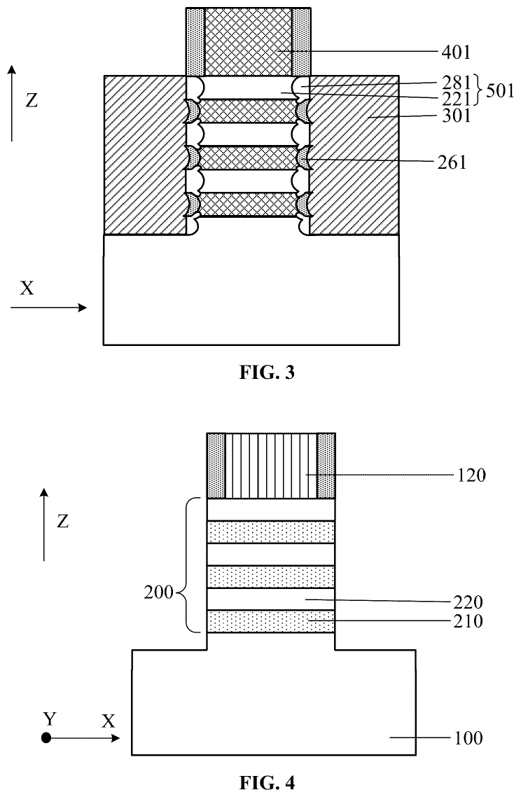

FIG. 2 illustrates a structural schematic of an exemplary semiconductor structure according to various disclosed embodiments of the present disclosure.

Referring to FIG. 2, a semiconductor structure may include a substrate 100; one or more channels 500 over the base substrate 100; a gate structure 400 around the one or more channels 500 along a vertical direction, where the gate structure 400 includes at least one first gate-structure portion 400a each around a channel 500 of the one or more channels 500; and first spacers 260a on two sides of each first gate-structure portion 400a along a lateral direction, where a portion of the channel 500 may extend into between the first gate-structure portion 400a and a corresponding first spacer 260a. The gate structure 400 may include at least one first gate-structure portion 400a and the second gate-structure portion 400b. The second gate-structure portion 400b may be above a source-drain doped layer 300; and the first gate-structure portion 400a may be below the second gate-structure portion 400b and between a source doped region and a drain doped region of the source-drain doped layer 300. The spacers 260 may include the first spacers 260a and the second spacers 260b. The second spacers 260b may be above the source-drain doped layer 300; and the first spacers 260a may be below the second spacers 260b and between the source doped region and the drain doped region of the source-drain doped layer 300. Along the vertical direction, the first gate-structure portion 400a and the corresponding first spacer 260a may be partially connected for providing an upper opening 600a and a bottom opening 600b there-between.

The base substrate 100 may provide the process operation basis for the fabrication process of the semiconductor structure. The semiconductor structures may include gate-all-around (GAA) transistors and fork-sheet transistors.

In some embodiments, the base substrate 100 may be made of silicon. In other embodiments, the base substrate may also be made of other materials including germanium, silicon germanium, silicon carbide, gallium arsenide, indium gallium and/or the like. The base substrate may also be made of other types of substrates including a silicon-on-insulator substrate, a germanium-on-insulator substrate and/or the like. The material of the base substrate may be a material suitable for process needs or easy to integrate.

The channel 500 may be configured to form a transistor channel.

For example, in some embodiments, one or more channels 500 may be spaced apart along the vertical direction (the Z direction as shown in FIG. 2).

In some embodiments, a portion of the channel 500 may extend into between the first gate-structure portion 400a and the first spacer 260a, which may increase the thickness of the isolation between the first gate-structure portion 400a and an external structure by the first spacer 260a, thereby enhancing the isolation between the first gate-structure portion 400a and external structure by the first spacer 260a and improving the performance of the semiconductor structure.

In some embodiments, a portion of the channel 500 may extend into between the top of the first spacer 260a and the first gate-structure portion 400a and between the bottom of the first spacer 260a and the first gate-structure portion 400a. That is, along the vertical direction, the first gate-structure portion 400a and the corresponding first spacer 260a may be partially connected for providing an upper opening 600a and a bottom opening 600b there-between, and the portion of the channel may extend into both the upper opening 600a and the bottom opening 600b.

In some embodiments, the gate structure 400 may be isolated from the source-drain doped layer by the first spacers 260. A portion of the channel 500 may extend into between the top of the first spacer 260a and the first gate-structure portion 400a, and between the bottom of the first spacer 260a and the first gate-structure portion 400a. That is, along the vertical direction, the first gate-structure portion 400a and the corresponding first spacer 260a are partially connected for providing an upper opening 600a and a bottom opening 600b there-between, and the portion of the channel extends into both the upper opening 600a and the bottom opening 600b. Therefore, the channel 500 extending between the top of the first spacer 260a and the first gate-structure portion 400a and between the bottom of the first spacer 260a and the first gate-structure portion 400a may increase the isolation thickness between the gate structure 400 and the source-drain doped layer at the top and bottom of the first spacer 260a, thereby being beneficial for enhancing the isolation between the gate structure 400 and the source-drain doped layer. Furthermore, during the formation of the gate structure 400, the channel 500 extending between the top of the first spacer 260a and the first gate-structure portion 400a and between the bottom of the first spacer 260a and the first gate-structure portion 400a, together with the first spacer 260a, may protect the sidewalls of the source-drain doped layer, thereby being beneficial for reducing the probability of damage to the sidewalls of the source-drain doped layer and improving the performance of the semiconductor structure.

In some embodiments, the channel 500 may be made of a material including silicon, germanium, silicon germanium, or a Group III-V semiconductor material. As an example, the material of the channel 500 may be silicon. In other embodiments, the material of the channel may be determined by the type and performance of the transistor.

The gate structure 400 may be configured to control turn-on and turn-off state of the transistor channel.

In some embodiments, the gate structure 400 may cross the channel 500 and surround the channel 500 along the extension of the gate structure 400.

The gate structure 400 may surround and cover the channel 500. Therefore, the top, bottom, and sidewalls of the channel 500 may be configured as the channel, which may increase the area of the channel 500 configured as the channel, thereby increasing the operating current of the semiconductor structure.

In some embodiments, the gate structure 400 may include a gate dielectric layer, surrounding the channel 500 along the extension of the gate structure 400, and a gate electrode layer on the gate dielectric layer.

The gate dielectric layer may isolate the gate electrode layer from the channel 500 and isolate the gate electrode layer from the base substrate 100.

The gate dielectric layer may be made of a material including HfO₂, ZrO₂, HfSiO, HfSiON, HfTaO, HfTiO, HfZrO, Al₂O₃, SiO₂, La₂O₃, and/or a combination thereof. In some embodiments, the gate dielectric layer may include a high-k gate dielectric layer; and the material of the high-k gate dielectric layer may include a high-k dielectric material. The high-k dielectric material refers to a dielectric material having a relative dielectric constant greater than the relative dielectric constant of silicon oxide. For example, the high-k gate dielectric layer may be made of a material including HfO₂, ZrO₂, HfSiO, HfSiON, HfTaO, HfTiO, HfZrO, Al₂O₃, and/or a combination thereof.

It should be noted that the gate dielectric layer may also include a gate oxide layer; and the gate oxide layer may be between the high-k gate dielectric layer and the channel 500. For example, the gate oxide layer may be made of silicon oxide.

In some embodiments, the gate structure 400 may be a metal gate structure. Therefore, the gate electrode layer may be made of a material including TiN, TaN, Ta, Ti, TiAl, W, Al, TiSiN, TiAlC, and/or a combination thereof.

For example, the gate electrode layer may include a work function layer (not shown), and an electrode layer (not shown) on the work function layer. The work function layer may be configured to adjust the threshold voltage of the transistor, and the electrode layer may be configured to lead out the electrical properties of the metal gate structure.

In other embodiments, the gate electrode layer may include only the work function layer.

In other embodiments, according to process requirements, the gate structure may also be a polysilicon gate structure.

The first spacer 260a may isolate the gate structure 400 from the source-drain doping layer, thereby reducing parasitic capacitance between the gate structure 400 and the source-drain doping layer.

It should be noted that the first spacer 260a refers to the inner spacer of the gate structure 400 between the channels 500 and between the channel 500 and the base substrate 100.

In some embodiments, the first spacer 260a may be made of a material including silicon nitride, silicon oxide, silicon oxycarbide, silicon oxycarbonitride, and/or a combination thereof.

The first spacer 260a, which is made of a material including silicon nitride, silicon oxide, silicon oxycarbide, silicon oxycarbonitride, and/or a combination thereof, may provide desirable isolation.

In some embodiments, the semiconductor structure may further include a source-drain doped layer 300 on the base substrate 100 at two sides of the gate structure 400 and in contact with the channel 500.

The source-drain doped layer 300 may be configured as the source region or the drain region of the transistor. For example, the doping type of the source-drain doped layer 300 may be same as the channel conductivity type of corresponding transistor.

The doping type of the source-drain doping layer 300 may be same as the channel conductivity type of corresponding transistor. For example, when the base substrate 100 is configured to form an NMOS (N-channel metal-oxide-transistor) transistor, the doping ions in the source-drain doping layer 300 may be N-type ions, including P ions, As ions, or Sb ions; and when the base substrate 100 is configured to form a PMOS (P-channel metal-oxide-transistor) transistor, the doping ions in the source-drain doping layer 300 may be P-type ions, including B ions, Ga ions, or In ions.

FIG. 3 illustrates another structural schematic of an exemplary semiconductor structure according to various disclosed embodiments of the present disclosure.

The similarity between one embodiment and above-mentioned embodiments are not be described in detail herein. The difference between one embodiment and above-mentioned embodiments is that the channel may include a channel layer and compensation layers on two sides of the channel layer.

Referring to FIG. 3, the channel 501 may include a channel layer 221 and a compensation layer 281 on two sides of the channel layer 221. The compensation layer 281 may extend into between the first gate-structure portion of the gate structure 401 and the spacer 261.

Accordingly, in some embodiments, one or more channel layers 221 may be spaced apart along the vertical direction (the Z direction as shown in FIG. 3). The channel layer 221 may be configured as the channel of the transistor.

In some embodiments, the channel layer 221 may be made of a material including silicon, germanium, silicon germanium, a Group III-V semiconductor material, and/or a combination thereof. As an example, the material of the channel layer 221 may be silicon. In other embodiments, the material of the channel layer may be determined by the type and performance of the transistor.

The compensation layer 281 may be configured to compensate the thickness of the spacer 261 near the edge of the channel layer 221; and together with the spacer 261, protect the sidewall of the source-drain doped layer 301. The compensation layer 281 may be also configured to, together with the channel layer 221, form the channel of the transistor.

In some embodiments, the compensation layer 281 may extend into between the top of the spacer 261 and the first gate-structure portion of the gate structure 401, and between the bottom of the spacer 261 and the first gate-structure portion of the gate structure 401. That is, along the vertical direction, the first gate-structure portion and the corresponding spacer 261 may be partially connected for providing an upper opening and a bottom opening there-between, and the compensation layer may extend into both the upper opening and the bottom opening.

In some embodiments, the gate structure 401 may be isolated from the source-drain doped layer 301 by the spacer 261 and the compensation layer 281. The compensation layer 281 may extend into between the top of the spacer 261 and the first gate-structure portion of the gate structure 401, and between the bottom of the spacer 261 and the first gate-structure portion of the gate structure 401. That is, along the vertical direction, the first gate-structure portion and the corresponding spacer 261 may be partially connected for providing an upper opening and a bottom opening there-between, and the compensation layer may extend into both the upper opening and the bottom opening. Therefore, the compensation layer 281 may increase the thickness of the isolation between the gate structure 401 and the source-drain doped layer at the top and bottom of the spacer 261, thereby being beneficial for enhancing the isolation between the gate structure 401 and the source-drain doped layer 301. Furthermore, during the formation of the gate structure 401, the compensation layer 281 and the spacer 261 may together protect the sidewall of the source-drain doped layer 301, thereby being beneficial for reducing the probability of damage to the sidewall of the source-drain doped layer 301 and improving the performance of the semiconductor structure.

In some embodiments, the thickness of the compensation layer 281 along the extension direction of the channel layer 221 (the X direction as shown in FIG. 3) may be about 20 Å to 150 Å.

The thickness of the compensation layer 281 may be about 20 to 150 Å, such that the compensation layer 281 may have sufficient protection effect. Furthermore, during the semiconductor manufacturing process, along the extension direction of the channel layer 221, a portion of the channel layer 221 may be removed to form a second groove exposing a sacrificial layer. The compensation layer 281 may be then formed in the second groove. The thickness of the compensation layer 281 may be about 20 to 150 Å, such that sufficient channel length of the channel layer 221 may be retained to ensure the performance of the channel layer 2210.

In some embodiments, the material of the compensation layer 281 may be same as the material of the channel layer 221.

During the semiconductor manufacturing process, along the extension direction of the channel layer 221, a portion of the channel layer 221 may be removed to form the second groove exposing the sacrificial layer. The compensation layer 281 may be then formed in the second groove. The source-drain doped layer 301 may be in contact with the compensation layer 281 and the spacer 261, that is, the compensation layer 281 and the channel layer 221 may together form the channel. The source-drain doped layer 301 may be epitaxially grown from the compensation layer 281. Therefore, the material of the compensation layer 281 may be same as the material of the channel layer 221, such that the compensation layer 281, together with the channel layer 221, may form the channel and facilitate epitaxial growth of the source-drain doped layer.

Accordingly, in some embodiments, the compensation layer 281 may be made of a material including silicon.

It should be noted that in some embodiments, the compensation layer 281 may be formed on two sides of the channel layer 221 using an epitaxial growth process. The compensation layer 281 may be made of same material as the channel layer 221. At this point, the channel 501 formed by the compensation layer 281 and the channel layer 221 may be considered a single-piece structure.

In other embodiments, the material of the compensation layer may be different from the material of the channel layer. For example, the material of the compensation layer may be selected based on actual process and device performance requirements.

In some embodiments, along the extension direction of the channel layer 221, the spacer 261 may protrude over the sidewall of the channel layer 221.

In the semiconductor manufacturing process, the sacrificial layer and the channel layer 221 which are stacked along the vertical direction may be first formed; along the extension direction of the channel layer 221, a portion of the sacrificial layer may be removed to form the first groove; the spacer 261 may be then formed in the first groove; and after the spacer 261 is formed, along the extension direction of the channel layer 221, a portion of the channel layer 221 may be removed to expose the sacrificial layer. Therefore, the spacer 261 may protrude over the sidewall of the channel layer 221.

It should be noted that during the removal of a portion of the sacrificial layer along the extension direction of the channel layer 221, the etching rate in the middle portion of the sacrificial layer may be greater than the etching rate at the edge where the sacrificial layer is in contact with the channel layer 221, which may result in the first groove that is concave inward along the extension direction of the channel layer 221. Accordingly, resulting spacer 261 may have the sickle-shaped morphology that tapers gradually from the middle toward the edge. Furthermore, during the formation of the spacer 261, filling of the middle portion of the first groove may be easier than filling of the corners at the edge of the first groove, such that the resulting spacer 261 may have the sickle-shaped morphology that tapers gradually from the middle toward the edge. That is, the spacer 261 may be thicker in the middle and thinner near the edge of the channel layer 221.

In some embodiments, the thickness of the spacer 261 along the extension direction of the channel layer 221 may be about 10 Å to 100 Å, which may be beneficial for ensuring the isolation effect of the spacer 261 and further ensuring that the gate structure 401 is wide enough to cover a sufficient portion of the channel layer 221.

In some embodiments, the material of the spacer 261 may be made of a material including silicon nitride, silicon oxide, silicon oxycarbide, silicon oxycarbonitride, and/or a combination thereof.

The spacer 261, which is made of a material including silicon nitride, silicon oxide, silicon oxycarbide, silicon oxycarbonitride, and/or a combination thereof, may provide desirable isolation.

Detailed description of the semiconductor structure in one embodiment may refer to corresponding description in above-mentioned embodiments, which may be not described in detail herein.

FIGS. 4-12 illustrate structural schematics corresponding to certain stages of a fabrication method of an exemplary semiconductor structure.

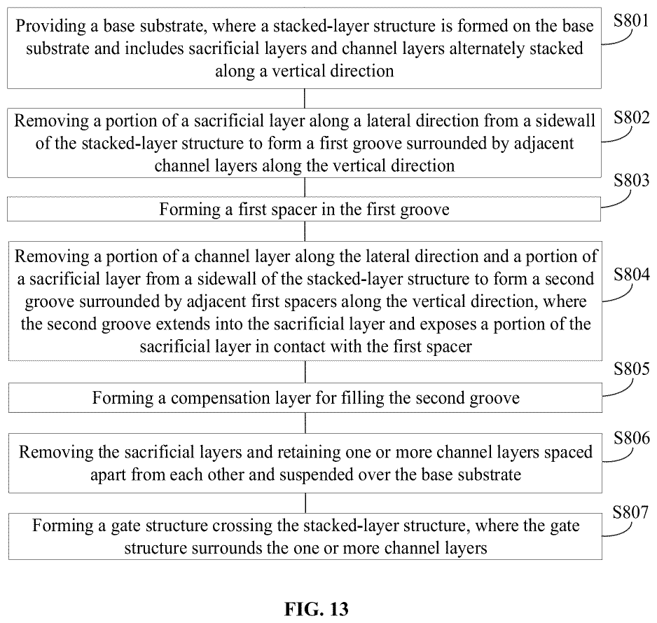

Referring to FIG. 4, the base substrate 100 may be provided; the stacked-layer structure 200 may be formed on the base substrate 100; and the stacked-layer structure 200 may include sacrificial layers 210 and channel layers 220 alternately stacked with each other along the vertical direction, that is, the Z direction as shown in FIG. 4 (e.g., in S801 of FIG. 13).

The base substrate 100 may provide the process operation basis for the fabrication process of the semiconductor structure. The semiconductor structures may include gate-all-around (GAA) transistors and fork-sheet transistors.

In some embodiments, the base substrate 100 may be made of silicon. In other embodiments, the base substrate may also be made of other materials including germanium, silicon germanium, silicon carbide, gallium arsenide, indium gallium and/or the like. The base substrate may also be made of other types of substrates including a silicon-on-insulator substrate, a germanium-on-insulator substrate and/or the like. The material of the base substrate may be a material suitable for process needs or easy to integrate.

The channel layer 220 in the stacked-layer structure 200 may be configured as the channel of the semiconductor structure. The sacrificial layer 210 may be configured to provide process basis for subsequent suspended arrangement of the channel layer 220 and may also be configured to occupy space for subsequently formed gate structure. In subsequent manufacturing processes, the sacrificial layer 210 may be removed to make the channel layer 220 to be suspended; and the gate structure may be then formed between the channel layer 220 and the base substrate 100, and between adjacent channel layers 220.

The surface of the channel layer 220 covered by the gate structure may be configured as the channel. In some embodiments, the top, bottom, and sidewalls of the channel layer 220 may all be configured as the channel, which may increase the area of the channel layer 220 available for the channel, thereby increasing the operating current of the semiconductor structure.

In some embodiments, for providing the base substrate 100, the channel layer 220 may be made of a material including silicon, germanium, silicon germanium, a Group III-V semiconductor material, and/or a combination thereof. As an example, the material of the channel layer 220 may be silicon. In other embodiments, the material of the channel layer may be determined by the type and performance of the transistor.

In some embodiments, for providing the base substrate 100, the sacrificial layer 210 may be made of a material including silicon germanium.

SiGe may have a lower etching resistance than silicon and achieve a higher etching selectivity with silicon. Therefore, the sacrificial layer 210 may be easier to be removed during subsequent removal process, which may reduce damage to the channel layer 220 when the sacrificial layer 210 is removed.

In other embodiments, according to the material of the channel layer, a material that has a suitable etching selectivity with the channel layer may be selected to form the sacrificial layer, which may reduce damage to the channel layer during subsequent removal of the sacrificial layer.

In some embodiments, a dummy gate structure 120 crossing the stacked-layer structure 200 may be formed on the base substrate 100 and cover the sidewalls and top of the stacked-layer structure 200.

The dummy gate structure 120 may cross the stacked-layer structure 200 along the direction perpendicular to the extension direction of the channel layer 220 (the Y direction as shown in FIG. 4) and cover the sidewalls and top of the stacked-layer structure 200 along the direction perpendicular to the extension direction of the channel layer 220.

The dummy gate structure 120 may be configured to occupy space for subsequent formation of the gate structure.

In some embodiments, the dummy gate structure 120 may be a stacked-layer structure, including a dummy gate oxide layer (not shown) and a dummy gate layer (not shown) covering the dummy gate oxide layer.

As an example, in some embodiments, the dummy gate oxide layer may be made of silicon oxide, and the dummy gate layer may be made of polysilicon.

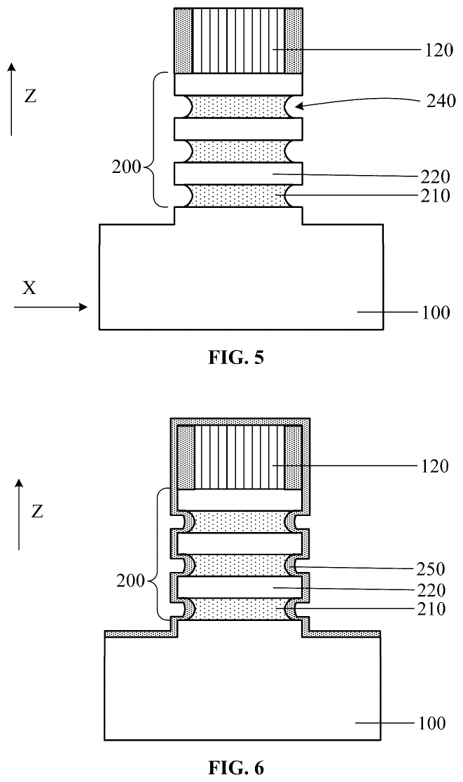

Referring to FIG. 5, a portion of the sacrificial layer 210 along the lateral direction may be removed from the sidewalls of the stacked-layer structure 200 to form the first groove 240 surrounded by adjacent channel layers 220 along the vertical direction (e.g., in S802 of FIG. 13).

For example, in some embodiments, a portion of the sacrificial layer 210 may be removed from the sidewalls of the stacked-layer structure 200 along the extension direction of the channel layer 220 (the X direction as shown in FIG. 5).

The first groove 240 may provide space for subsequent formation of the spacer.

In some embodiments, an isotropic etching process may be configured to remove a portion of the sacrificial layer 210 to form the first groove 240 surrounded by adjacent channel layers 220 along the vertical direction.

The etching parameters of the isotropic etching process may be easy to be controlled and may achieve a relatively high etching selectivity, thereby removing a portion of the sacrificial layer 210 while reducing damage to the channel layer 220.

It should be noted that during the etching process of the sacrificial layer 210, the middle portion of the sacrificial layer 210 may be more easily exposed than the edge portion contacting the channel layer 220. Therefore, the etching rate of the middle portion of the sacrificial layer 210 may be greater than the etching rate of the edge portion contacting the channel layer 220. Furthermore, the germanium doping concentration in the sacrificial layer 210 may gradually decrease from the middle portion toward the edge portion contacting the channel layer 220, such that the etching rate of the middle portion of the sacrificial layer 210 may be greater than the etching rate of the edge portion contacting the channel layer 220. Therefore, the first groove 240 may have a concave shape along the extension direction of the channel layer 220.

In some embodiments, for removing a portion of the sacrificial layer 210 to form the first groove 240 surrounded by adjacent channel layers 220 along the vertical direction, the dimension of the first groove 240 along the extension direction of the channel layer 220 may be about 10 Å to 100 Å, which may be beneficial for ensuring sufficient space for subsequent formation of the spacer and gate structure.

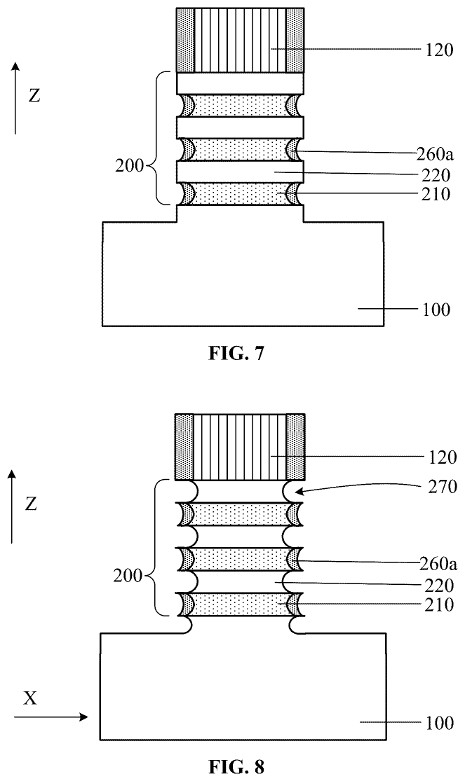

Referring to FIGS. 6-7, the first spacer 260a may be formed in the first groove 240 (e.g., in S803 of FIG. 13).

The first spacer 260a may be configured to isolate the gate structure and the source-drain doped layer subsequently formed, thereby reducing parasitic capacitance between the gate structure and the source-drain doped layer.

It should be noted that the first groove 240 may be concave along the extension direction of the channel layer 220. Accordingly, resulting first spacer 260a may have the sickle-shaped morphology that tapers gradually from the middle toward the edge. Furthermore, during the formation of the first spacer 260a, filling of the middle portion of the first groove 240 may be easier than filling of the corners at the edge of the first groove 240, such that the resulting first spacer 260a may have the sickle-shaped morphology that tapers gradually from the middle toward the edge. That is, the first spacer 260a may be thicker in the middle and thinner near the edge of the channel layer 220.

Accordingly, in some embodiments, for forming the first spacer 260a in the first groove 240, the thickness of the first spacer 260a along the extension direction of the channel layer 220 may be about 10 Å to 100 Å, which may be beneficial for ensuring the isolation effect of the first spacer 260a and further ensuring that the first spacer 260a has sufficient width along the extension direction of the channel layer 220 to form the gate structure.

In some embodiments, for forming the first spacer 260a in the first groove 240, the first spacer 260a may be made of a material including silicon nitride, silicon oxide, silicon oxycarbide, silicon oxycarbonitride, and/or a combination thereof.

The first spacer 260a, which is made of a material including silicon nitride, silicon oxide, silicon oxycarbide, silicon oxycarbonitride, and/or a combination thereof, may provide desirable isolation.

For example, referring to FIG. 6, forming the first spacer 260a in the first groove 240 may include forming a spacer material layer 250 that covers the sidewalls of the channel layer 220 and fills the first groove 240.

The spacer material layer 250 may be configured to form the first spacer 260a.

In some embodiments, for forming the spacer material layer 250 covering the sidewalls of the channel layer 220 and filling the first groove 240, filling of the middle portion of the first groove 240 may be easier than filling of the corners at the edge of the first groove 240, such that the spacer material layer 250 formed in the first groove may have the sickle-shaped morphology that tapers gradually from the middle toward the edge.

For example, in some embodiments, for forming the spacer material layer 250 covering the sidewalls of the channel layer 220 and filling the first groove 240, the spacer material layer 250 may also cover the top and sidewalls of the dummy gate structure 120 and the top of the base substrate 100.

Referring to FIG. 7, the spacer material layer 250 on the sidewalls of the channel layer 220 may be removed, and the spacer material layer 250 in the first groove 240 may be retained as the first spacer 260a.

Accordingly, retaining (remaining) first spacer 260a may form the sickle-shaped morphology that tapers gradually from the middle toward the edge.

For example, in some embodiments, for removing the spacer material layer 250 on the sidewalls of the channel layer 220, the spacer material layer 250 on the top and sidewalls of the dummy gate structure 120, and the top of the base substrate 100 may be also removed.

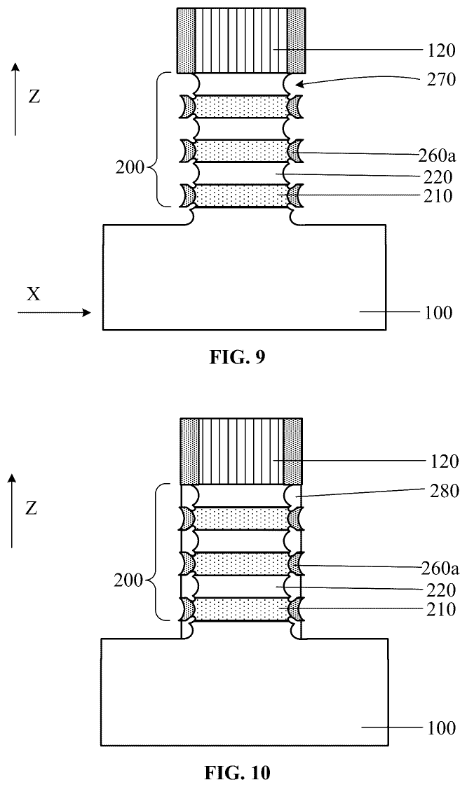

Referring to FIGS. 8-9, a portion of the channel layer 220 and a portion of the sacrificial layer 210 may be removed from the sidewalls of the stacked-layer structure 200 to form a second groove 270, which is surrounded by adjacent first spacers 260 along the vertical direction; and the second groove 270 may extend into the sacrificial layer 210 and expose a portion of the sacrificial layer 210 which is in contact with the first spacer 260a (e.g., in S804 of FIG. 13).

For example, in some embodiments, along the extension direction of the channel layer 220, a portion of the channel layer 220 and a portion of the sacrificial layer 210 may be removed from the sidewalls of the stacked-layer structure 200.

The second groove 270 may extend into the sacrificial layer 210, which may provide space for forming the compensation layer between the first spacer 260a and the sacrificial layer 210.

In some embodiments, for removing a portion of the channel layer 220 and a portion of the sacrificial layer 210 from the sidewalls of the stacked-layer structure 200 to form the second groove 270 surrounded by adjacent first spacers 260 along the vertical direction, the width of the second groove 270 along the extension direction of the channel layer 220 may be about 20 Å to 150 Å.

The width of the second groove 270 along the extension direction of the channel layer 220 may be 20 Å to 150 Å, such that the compensation layer of sufficient thickness may be formed, and sufficient channel length of the channel layer 220 may be retained, thereby ensuring the operational performance of the channel layer 220.

For example, referring to FIG. 8, removing a portion of the channel layer 220 and a portion of the sacrificial layer 210 from the sidewalls of the stacked-layer structure 200 to form the second groove 270 surrounded by adjacent first spacers 260 along the vertical direction, and the second groove 270 extending into the sacrificial layer 210 and exposing the portion of the sacrificial layer 210 in contact with the first spacer 260a may include removing a portion of the channel layer 220 from the sidewalls of the stacked-layer structure 200 to form the second groove 270 exposing a portion of the sacrificial layer 210 in contact with the first spacer 260a.

Removing a portion of the channel layer 220 to form the second groove 270 exposing a portion of the sacrificial layer 210 in contact with the first spacer 260a may be configured to prepare for removing the portion of the sacrificial layer 210.

In some embodiments, an isotropic etching process may be configured to remove a portion of the channel layer 220 from the sidewalls of the stacked-layer structure 200 to form the second groove 270 exposing a portion of the sacrificial layer 210 in contact with the first spacer 260a.

The etching parameters of the isotropic etching process may be easy to be controlled and may achieve a relatively high etching selectivity, thereby removing a portion of the channel layer 220 while reducing damage to the sacrificial layer 210 and the first spacer 260a.

In some embodiments, during the isotropic etching process, the etching selectivity between the channel layer 220 and the sacrificial layer 210 may be greater than or equal to 3, such that the damage to the sacrificial layer 210 may be reduced during the removal of a portion of the channel layer 220. The etching selectivity between the channel layer 220 and the first spacer 260a may be greater than or equal to 3, such that the damage to the first spacer 260a may be reduced during the removal of a portion of the channel layer 220.

Referring to FIG. 9, the portion of the sacrificial layer 210 exposed at the top and bottom of the first spacers 260 may be removed, such that the second groove 270 may extend into the sacrificial layer 210.

The portion of the sacrificial layer 210 may be removed by the second groove 270 between adjacent side walls 260 along the vertical direction. In such way, removed portion of the sacrificial layer 210 may be the sacrificial layer 210 in contact with the top and bottom of the first spacer 260a, and the second groove 270 may extend into the sacrificial layer 210. The second groove 270 may extend into between the top/bottom edges of the first spacer 260a and remaining sacrificial layer 210, which may be configured for preparation of the formation of the compensation layer between the top/bottom edges of the first spacer 260a and remaining sacrificial layer 210.

In some embodiments, an isotropic etching process may be configured to remove the portion of the sacrificial layer 210 exposed at the top and bottom of the first spacer 260a, such that the second groove 270 may be extend into the sacrificial layer 210.

The etching parameters of the isotropic etching process may be easy to be controlled and may achieve a relatively high etching selectivity, thereby removing a portion of the sacrificial layer 210 while reducing damage to the channel layer 220 and the first spacer 260a.

In some embodiments, during the isotropic etching process, the etching selectivity between the sacrificial layer 210 and the channel layer 220 may be greater than or equal to 5, such that the damage to the channel layer 220 may be reduced during the removal of a portion of the sacrificial layer 210. The etching selectivity between the sacrificial layer 210 and the first spacer 260a may be greater than or equal to 5, such that the damage to the first spacer 260a may be reduced during the removal of a portion of the sacrificial layer 210.

In other embodiments, the isotropic etching process may be used in a single etching step to remove a portion of the channel layer and a portion of the sacrificial layer from the sidewalls of the stacked-layer structure along the extension direction of the channel layer, thereby forming the second groove surrounded by adjacent spacers along the vertical direction; and the second groove may extend into the sacrificial layer and expose a portion of the sacrificial layer in contact with the spacer.

Correspondingly, in other embodiments, during the isotropic etching process, the etching selectivity between the channel layer and the sacrificial layer may be greater than or equal to 3. That is, a desirable etching selectivity may be selected, such that a portion of the channel layer may be removed while also removing a small portion of the sacrificial layer. Therefore, in a single etching step, the second groove, surrounded by adjacent spacers along the vertical direction and extending into the sacrificial layer, may be formed.

Referring to FIG. 10, a compensation layer 280 may be formed to fill the second groove 270 (e.g., in S805 of FIG. 13).

The compensation layer 280 may be configured to compensate the thickness of the first spacer 260a near the edge of the channel layer 220; and together with the first spacer 260a, protect the sidewalls of subsequently formed source-drain doped layer.

In some embodiments, the gate structure and the source-drain doped layer which are subsequently formed may be isolated (separated) from each other by the first spacers 260 and the compensation layer 280; and the second groove 270 may extend from between vertically adjacent first spacers 260 into the sacrificial layer 210. That is, the second groove 270 may extend to the positions where the top and bottom of the first spacers 260 are in contact with the sacrificial layer 210. Therefore, the compensation layer 280 may increase the thickness of the isolation between the gate structure and the source-drain doped layer subsequently formed at the top and bottom of the first spacer 260a, thereby being beneficial for enhancing the isolation between the gate structure and the source-drain doped layer. Furthermore, during subsequent removal of the sacrificial layer 210, the compensation layer 280 and the first spacer 260a may together protect the sidewalls of the source-drain doped layer, thereby being beneficial for reducing the probability of damage to the sidewalls of the source-drain doped layer and further improving the performance of the semiconductor structure.

Accordingly, in some embodiments, for forming the compensation layer 280 to fill the second groove 270, the thickness of the compensation layer 280 along the extension direction of the channel layer 220 may be about 20 Å to 150 Å.

In some embodiments, an epitaxial growth process may be configured to form the compensation layer 280 for filling the second groove 270.

The epitaxial growth process may have desirable control of process parameters and relatively high process controllability, such that relatively precise thickness for the compensation layer 280 may be obtained. Furthermore, the epitaxial growth process may facilitate the formation of the film with less impurities, which may result in relatively high quality compensation layer 280.

In some embodiments, for forming the compensation layer 280 to fill the second groove 270, the material of the compensation layer 280 may be same as the material of the channel layer 220.

In the semiconductor manufacturing process, the compensation layer 280 and the channel layer 220 may also together form the channel. Subsequent source-drain doping layer may be formed by epitaxial growth of the compensation layer 280. Therefore, the material of the compensation layer 280 may be same as the material of the channel layer 220. In such way, the compensation layer 280 and the channel layer 220 may together form the channel, and epitaxial growth of the source-drain doping layer 300 may be easily performed.

Furthermore, the material of the compensation layer 280 may be same as the material of the channel layer 220, such that relatively high etching selectivity may be between the sacrificial layer 210 and the compensation layer 280 during subsequent removal of the sacrificial layer 210, thereby reducing damage to the compensation layer 280 during subsequent removal of the sacrificial layer 210 and ensuring that the compensation layer 280 compensates the thickness of the top and bottom edges of the first spacer 260a.

Accordingly, in some embodiments, for forming the compensation layer 280 to fill the second groove 270, the compensation layer 280 may be made of a material including silicon.

It should be noted that in one embodiment, the compensation layer 280 for filling the second groove 270 may be formed using an epitaxial growth process; the material of the compensation layer 280 may be same as the material of the channel layer 220; and the compensation layer 280 and the channel layer 220 may form a single-piece structure.

In other embodiments, the materials of the compensation layer and the channel layer may be different.

In some embodiments, before subsequently forming the source-drain doped layer on the base substrate on two sides of the stacked-layer structure, the sidewalls of the compensation layer 280 may be etched back to ensure desirable vertical smoothness of the sidewalls of the compensation layer 280, thereby being beneficial for improving spacing consistency between the gate structure and the source-drain doped layer subsequently formed.

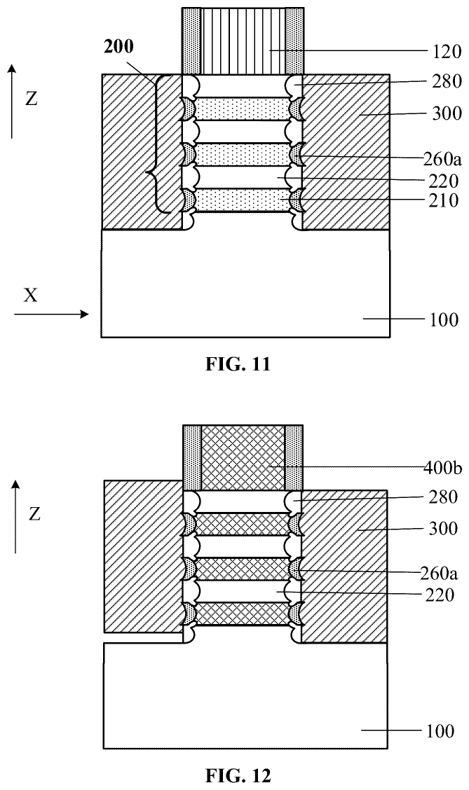

Referring to FIG. 11, the source-drain doped layer 300 may be formed on the base substrate 100 at two sides of the stacked-layer structure 200. The source-drain doped layer 300 may be in contact with the compensation layer 280 and the first spacers 260.

The source-drain doped layer 300 may be configured as the source region or the drain region of the transistor. For example, the doping type of the source-drain doped layer 300 may be same as the channel conductivity type of corresponding transistor.

For example, when the base substrate 100 is configured to form an NMOS (N-channel metal-oxide-transistor) transistor, the doping ions in the source-drain doping layer 300 may be N-type ions, including P ions, As ions, or Sb ions; and when the base substrate 100 is configured to form a PMOS (P-channel metal-oxide-transistor) transistor, the doping ions in the source-drain doping layer 300 may be P-type ions, including B ions, Ga ions, or In ions.

In some embodiments, the compensation layer 280 and the channel layer 220 may be made of same material, such that the epitaxial growth process may be configured to effectively form the source-drain doping layer 300.

Referring to FIG. 12, the dummy gate structure 120 may be removed to form a gate structure opening; the sacrificial layer 210 may be removed; and one or more channel layers 220, spaced apart from each other and suspended over the base substrate 100, may be retained (e.g., in S806 of FIG. 13).

The gate structure opening and the location for removing the sacrificial layer 210 may provide space for subsequent formation of the gate structure.

In some embodiments, during the removal of the sacrificial layer 210, the compensation layers 280 may be formed at the top and bottom edges of the first spacers 260, which may increase the protective thickness at the top and bottom edges of the first spacers 260, thereby being beneficial for improving the protection for the source-drain doped layer 300 and reducing the probability of damage to the source-drain doped layer 300.

In some embodiments, an isotropic etching process may be configured to remove the sacrificial layer 210.

The isotropic etching process may have relatively low process costs, simple steps, and relatively high etching selectivity, thereby being beneficial for reducing damage to the channel layer 220 and the compensation layer 280 during the removal of the sacrificial layer 210.

Referring to FIG. 12, the gate structure 400 crossing the channel layer structure 230 may be formed; and the gate structure 400 may surround the channel layer 220 (e.g., in S807 of FIG. 13).

The gate structure 400 may be configured to control turn-on and turn-off state of the transistor channel.

The gate structure 400 may surround and cover the channel layer 220. Therefore, the top, bottom, and sidewalls of the channel layer 220 may be configured as the channel, which may increase the area of the channel layer 220 configured as the channel, thereby increasing the operating current of the semiconductor structure.

In some embodiments, the gate structure 400 may include a gate dielectric layer, surrounding the channel layer 220 along the extension of the gate structure 400, and a gate electrode layer on the gate dielectric layer.

The gate dielectric layer may isolate the gate electrode layer from the channel layer 220 and isolate the gate electrode layer from the base substrate 100.

The gate dielectric layer may be made of a material including HfO₂, ZrO₂, HfSiO, HfSiON, HfTaO, HfTiO, HfZrO, Al₂O₃, SiO₂, La₂O₃, and/or a combination thereof. In some embodiments, the gate dielectric layer may include a high-k gate dielectric layer; and the material of the high-k gate dielectric layer may include a high-k dielectric material. The high-k dielectric material refers to a dielectric material having a relative dielectric constant greater than the relative dielectric constant of silicon oxide. For example, the high-k gate dielectric layer may be made of a material including HfO₂, ZrO₂, HfSiO, HfSiON, HfTaO, HfTiO, HfZrO, Al₂O₃, and/or a combination thereof.

It should be noted that the gate dielectric layer may also include a gate oxide layer; and the gate oxide layer may be between the high-k gate dielectric layer and the channel layer 220. For example, the gate oxide layer may be made of silicon oxide.

In some embodiments, the gate structure 400 may be a metal gate structure. Therefore, the gate electrode layer may be made of a material including TiN, TaN, Ta, Ti, TiAl, W, Al, TiSiN, TiAlC, and/or a combination thereof.

For example, the gate electrode layer may include a work function layer (not shown), and an electrode layer (not shown) on the work function layer. The work function layer may be configured to adjust the threshold voltage of the transistor, and the electrode layer may be configured to lead out the electrical properties of the metal gate structure.

In other embodiments, the gate electrode layer may include only the work function layer.

In other embodiments, according to process requirements, the gate structure may also be a polysilicon gate structure.

Accordingly, in some embodiments, the gate structure 400 between adjacent channel layers 220 and between the channel layers 220 and the base substrate 100 may be in contact with the first spacer 260a and the compensation layer 280 on the sidewalls of the gate structure 400. The first spacer 260a and the compensation layer 280 may together provide effective isolation between the gate structure 400 and the source-drain doped layer 300.

It should be noted that the semiconductor structure in above-mentioned embodiments may be formed using the fabrication method of the semiconductor structure in one embodiment or using other methods.

Although the present disclosure has been disclosed above, the present disclosure may be not limited thereto. Any changes and modifications may be made by those skilled in the art without departing from the spirit and scope of the disclosure, and the scope of the disclosure should be determined by the scope defined by the appended claims.

What is claimed is

1. A semiconductor structure, comprising:
a base substrate;
one or more channels over the base substrate;
a gate structure around the one or more channels along a vertical direction, wherein the gate structure includes at least one first gate-structure portion each around a channel of the one or more channels; and
first spacers on two sides of each first gate-structure portion along a lateral direction, wherein a portion of the channel extends into between the first gate-structure portion and a corresponding first spacer.

2. The semiconductor structure according to claim 1, wherein:
along the vertical direction, the first gate-structure portion and the corresponding first spacer are partially connected for providing an upper opening and a bottom opening there-between, and the portion of the channel extends into both the upper opening and the bottom opening.

3. The semiconductor structure according to claim 1, wherein:
the channel includes a channel layer and a compensation layer on two sides of the channel layer; and the compensation layer extends into between the first gate-structure portion and the corresponding first spacer.

4. The semiconductor structure according to claim 3, wherein:
along the vertical direction, the first gate-structure portion and the corresponding first spacer are partially connected for providing an upper opening and a bottom opening there-between, and the compensation layer extends into both the upper opening and the bottom opening.

5. The semiconductor structure according to claim 3, wherein:
along an extension direction of the channel layer, a thickness of the compensation layer is about 20 Å to 150 Å.

6. The semiconductor structure according to claim 3, wherein:
the channel layer is made of a material including silicon, germanium, silicon germanium, a Group III-V semiconductor material, or a combination thereof.

7. The semiconductor structure according to claim 6, wherein:
a material of the compensation layer is same as the material of the channel layer.

8. The semiconductor structure according to claim 7, wherein:
the compensation layer is made of a material including silicon.

9. The semiconductor structure according to claim 3, wherein:
the first spacer protrudes over a sidewall of the channel layer along the lateral direction; and
along an extension direction of the channel layer, a thickness of the first spacer is about 10 Å to 100 Å.

10. The semiconductor structure according to claim 1, wherein:
the first spacer is made of silicon nitride, silicon oxide, silicon oxycarbide, and silicon oxycarbonitride, and/or a combination thereof.

11. The semiconductor structure according to claim 1, further including:
a source-drain doped layer, on the base substrate at two sides of the gate structure and in contact with the one or more channels.

12. A fabrication method of a semiconductor structure, comprising:
providing a base substrate, wherein a stacked-layer structure is formed on the base substrate and includes sacrificial layers and channel layers alternately stacked along a vertical direction;
removing a portion of a sacrificial layer along a lateral direction from a sidewall of the stacked-layer structure to form a first groove surrounded by adjacent channel layers along the vertical direction;
forming a first spacer in the first groove;
removing a portion of a channel layer along the lateral direction and a portion of a sacrificial layer from a sidewall of the stacked-layer structure to form a second groove surrounded by adjacent first spacers along the vertical direction, wherein the second groove extends into the sacrificial layer and exposes a portion of the sacrificial layer in contact with the first spacer;
forming a compensation layer for filling the second groove;
removing the sacrificial layers and retaining one or more channel layers spaced apart from each other and suspended over the base substrate; and
forming a gate structure crossing the stacked-layer structure, wherein the gate structure surrounds the one or more channel layers.

13. The fabrication method according to claim 12, wherein forming the first spacer in the first groove includes:
forming a spacer material layer covering a sidewall of the channel layer and filling the first groove; and
removing the spacer material layer on the sidewall of the channel layer and retaining the spacer material layer in the first groove as the first spacer.

14. The fabrication method according to claim 12, wherein removing the portion of the channel layer along the lateral direction and the portion of the sacrificial layer from the sidewall of the stacked-layer structure to form the second groove surrounded by adjacent first spacers along the vertical direction includes:
removing the portion of the channel layer along the lateral direction from the sidewall of the stacked-layer structure to form the second groove exposing the portion of the sacrificial layer in contact with the first spacer; and
removing a portion of the sacrificial layer exposed at a top and a bottom of the first spacer, such that the second groove extend into the sacrificial layer.

15. The fabrication method according to claim 14, wherein:
an isotropic etching process is configured to remove the portion of the channel layer along the lateral direction from the sidewall of the stacked-layer structure to form the second groove exposing the portion of the sacrificial layer in contact with the first spacer; and/or in the isotropic etching process, an etching selectivity ratio between the channel layer and the sacrificial layer is greater than or equal to 3, and an etching selectivity ratio between the channel layer and the first spacer is greater than or equal to 3.

16. The fabrication method according to claim 13, wherein:
an isotropic etching process is configured to remove the portion of the sacrificial layer exposed at the top and the bottom of the first spacer, such that the second groove extend into the sacrificial layer; and/or
in the isotropic etching process, an etching selectivity between the sacrificial layer and the channel layer is greater than or equal to 5, and an etching selectivity between the sacrificial layer and the first spacer is greater than or equal to 5.

17. The fabrication method according to claim 12, wherein:
an isotropic etching process is configured to remove the portion of the channel layer along the lateral direction and the portion of the sacrificial layer from the sidewall of the stacked-layer structure to form the second groove surrounded by adjacent first spacers along the vertical direction; and the second groove extends into the sacrificial layer and exposes the portion of the sacrificial layer in contact with the first spacer; and/or
in the isotropic etching process, an etching selectivity ratio between the channel layer and the sacrificial layer is greater than or equal to 3.

18. The fabrication method according to claim 12, wherein:
for removing the portion of the channel layer along the lateral direction and the portion of the sacrificial layer from the sidewall of the stacked-layer structure to form the second groove surrounded by adjacent first spacers along the vertical direction, a width of the second groove is about 20 Å to 150 Å.

19. The fabrication method according to claim 12, wherein:
an epitaxial growth process is configured to form the compensation layer for filling the second groove; and/or
for forming the compensation layer for filling the second groove, a material of the compensation layer is same as a material of the channel layer; and/or
for providing the base substrate, the channel layer is made of a material including silicon, germanium, silicon germanium, a Group III-V semiconductor material, or a combination thereof; and the sacrificial layer is made of a material including silicon germanium.

20. The fabrication method according to claim 12, before removing the sacrificial layer, further including:
forming a source-drain doped layer on the base substrate at two sides of the stacked-layer structure, wherein the source-drain doped layer is in contact with the compensation layer and the first spacer.
